(19) United States
(12) Patent Application Publication
(10) Pub. No.: US 2026/0237054 A1
(43) Pub. Date: Aug. 13, 2026

(54) METHOD OF DETECTING DEFECTIVE SEMICONDUCTOR PACKAGE

(71) Applicant: SAMSUNG ELECTRONICS CO., LTD., Suwon-si (KR)

(72) Inventors: Sunghyun KIM, Suwon-si (KR); Ikjong PARK, Suwon-si (KR); Jeongmin PARK, Suwon-si (KR); Dongsoo LEE, Suwon-si (KR); Daeha HWANG, Suwon-si (KR)

(73) Assignee: SAMSUNG ELECTRONICS CO., LTD., Suwon-si (KR)

(21) Appl. No.: 19/409,132

(22) Filed: Dec. 4, 2025

(30) Foreign Application Priority Data
Feb. 13, 2025 (KR) 10-2025-0018792

(51) Int. Cl. G06T 7/00; G01R 31/311

(52) U.S. Cl. CPC G06T 7/001; G01R 31/311; G06T 2207/30148

(57) ABSTRACT

Provided is a method of detecting a defective semiconductor package, the method including setting a detection threshold point, which is a reference point to determine a defective flux application, obtaining a target image of a first surface of a package substrate, performing a rule-based defect detection algorithm on the target image, performing a deep learning-based defect detection algorithm on the target image, performing a hybrid defect detection algorithm based on a result value of performing the rule-based defect detection algorithm and a result value of performing the deep learning-based defect detection algorithm, and comparing a defect probability obtained based on the hybrid defect detection algorithm with a size of the detection threshold point to determine whether the flux application of the package substrate is defective.

### CROSS-REFERENCE TO RELATED APPLICATION

This application claims priority to Korean Patent Application No. 10-2025-0018792, filed on Feb. 13, 2025, in the Korean Intellectual Property Office, the disclosure of which is incorporated by reference herein in its entirety.

### BACKGROUND

Embodiments of the present disclosure relate to a method of detecting a defective semiconductor package, and more particularly, to a method of determining whether flux application used in a solder ball process is normal.

With the rapid development of the electronics industry and the demands of users, electronic devices have become smaller and lighter. As electronic devices have become smaller and lighter, semiconductor packages used in electronic devices have also become smaller and lighter, and semiconductor packages are also required to have high reliability along with high performance and high capacity. As semiconductor packages have had high performance and high capacity, the power consumption of semiconductor packages has increased. Accordingly, the importance of the structure of semiconductor packages that corresponds to the size/performance of the semiconductor packages and provides stable power supply to the semiconductor packages, as well as a method of determining whether a semiconductor package is defective, has increased.

### SUMMARY

One or more embodiments provide a method of detecting a defective semiconductor package with improved reliability.

According to an aspect of one or more embodiments, there is provided a method of detecting a defective semiconductor package, the method including setting a detection threshold point, which is a reference point to determine a defective flux application, obtaining a target image of a first surface of a package substrate, performing a rule-based defect detection algorithm on the target image, performing a deep learning-based defect detection algorithm on the target image, performing a hybrid defect detection algorithm based on a result value of performing the rule-based defect detection algorithm and a result value of performing the deep learning-based defect detection algorithm, and comparing a defect probability obtained based on the hybrid defect detection algorithm with a size of the detection threshold point to determine whether the flux application of the package substrate is defective.

According to another aspect of one or more embodiments, there is provided a method of detecting a defective semiconductor package, the method including setting a detection threshold point, which is a reference point to determine a defective flux application, obtaining a target image of a first surface of a package substrate, performing a rule-based defect detection algorithm on the target image, performing a deep learning-based defect detection algorithm on the target image, performing a hybrid defect detection algorithm based on a result value of performing the rule-based defect detection algorithm and a result value of performing the deep learning-based defect detection algorithm, and comparing a defect probability obtained through the hybrid defect detection algorithm with a size of the detection threshold point to determine whether the flux application of the package substrate is defective, wherein, in the determining of whether the flux application of the package substrate is defective, the flux application of the package substrate is determined to be normal based on the defect probability being smaller than the detection threshold point, and the flux application of the package substrate is determined to be defective based on the defect probability being greater than the detection threshold point, and wherein the acquiring of the target image includes introducing the package substrate, aligning the introduced package substrate, capturing a ball land image of the package substrate, dotting flux on the package substrate, capturing an image of the flux, inspecting a state of the flux, picking up a ball to be attached to the flux, dotting the ball and inspecting a state of the ball, and discharging the package substrate.

According to still another aspect of one or more embodiments, there is provided a method of detecting a defective semiconductor package, the method including setting a detection threshold point, which is a reference point to determine a defective flux application, obtaining a target image of a first surface of a printed circuit board (PCB), performing a rule-based defect detection algorithm on the target image, performing a deep learning-based defect detection algorithm on the target image, performing a hybrid defect detection algorithm based on a result value of the performing each of the rule-based defect detection algorithm and based on a result value of the deep learning-based defect detection algorithm, and comparing a defect probability obtained through the hybrid defect detection algorithm with a size of the detection threshold point to determine whether the PCB is defective, wherein, in the determining of whether the PCB is defective, a flux application on the PCB is determined to be normal based on the defect probability being smaller than the detection threshold point, and the flux application on the PCB is determined to be defective based on the defect probability being greater than the detection threshold point, wherein the obtaining of the target image includes introducing a PCB, aligning the introduced PCB, capturing a ball land image of the PCB, dotting flux onto the PCB, capturing an image of the flux, inspecting a state of the flux, picking up a ball to be attached to the flux, dotting the ball and inspecting a state of the ball, and discharging the PCB, wherein the rule-based defect detection algorithm includes indexing a fiducial mark on the PCB, aligning the ball land image with the flux image, cropping a package region from a full image obtained by adding the aligned ball land image to the flux image, segmenting a ball land region from the full image, obtaining a difference image between the ball land image and the flux image, segmenting a flux region from the full image and extracting features of the segmented region, and determining whether the state of the flux is normal based on the features extracted from the segmenting the flux region in the full image and extracting the features of the segmented region, and wherein the hybrid defect detection algorithm includes a vector combining a feature point vector of the rule-based defect detection algorithm and a feature point vector of the deep learning-based defect detection algorithm.

### BRIEF DESCRIPTION OF DRAWINGS

Embodiments will be more clearly understood from the following detailed description taken in conjunction with the accompanying drawings in which:

FIG. 1 is a cross-sectional view of a semiconductor package that is a target of a method of detecting a defective semiconductor package, according to one or more embodiments;

FIGS. 2, 3, 4, 5, and 6 are cross-sectional views schematically illustrating a process of applying flux in a solder ball process of a semiconductor package that is a target of a method of detecting a defective semiconductor package, according to one or more embodiments;

FIG. 7 is a flowchart of a method of detecting a defective semiconductor package, according to one or more embodiments;

FIG. 8 is a flowchart of operations of acquiring a target image included in a method of detecting a defective semiconductor package, according to one or more embodiments;

FIG. 9 is a flowchart of a rule-based defect detection algorithm included in a method of detecting a defective semiconductor package, according to one or more embodiments;

FIG. 10 is a flowchart of operations of segmenting a flux region and extracting features of the corresponding region, included in a method of detecting a defective semiconductor package, according to one or more embodiments;

FIG. 11 is a flowchart of an operation of extracting features of a flux region included in a method of detecting a defective semiconductor package, according to one or more embodiments;

FIGS. 12 and 13 are result values of simulations of a rule-based defect detection algorithm included in a method of detecting a defective semiconductor package, according to one or more embodiments;

FIG. 14 is a flowchart of a deep learning-based defect detection algorithm included in a method of detecting a defective semiconductor package, according to one or more embodiments;

FIG. 15 is a diagram illustrating an operation of performing data collection and labeling included in a method of detecting a defective semiconductor package, according to one or more embodiments;

FIG. 16 is a graph illustrating a defect probability for an algorithm sensitivity included in a method of detecting a defective semiconductor package, according to one or more embodiments;

FIG. 17 is result values for a simulation of a deep learning-based defect detection algorithm included in a method of detecting a defective semiconductor package, according to one or more embodiments;

FIG. 18 is a diagram illustrating data for performing a hybrid defect detection algorithm included in a method of detecting a defective semiconductor package, according to one or more embodiments;

FIG. 19 is a diagram illustrating vectors representing the logic of a hybrid defect detection algorithm included in a method of detecting a defective semiconductor package, according to one or more embodiments; and

FIG. 20 is a configuration diagram illustrating a defective semiconductor package detection device for implementing a method of detecting a defective semiconductor package, according to one or more embodiments.

### DETAILED DESCRIPTION

The embodiments may have various modifications and may take various forms, and some embodiments are illustrated in the drawings and described in detail. However, the present embodiments are not intended to be limited to a particular disclosure form. In addition, the embodiments described below are merely examples, and various modifications may be made from these embodiments.

Any use of examples or terms is intended merely to elaborate technical ideas and is not intended to limit the scope of the inventive concept unless otherwise defined by the claims.

Unless otherwise specifically stated, in this specification, a vertical direction may be defined as the Z direction, and a first horizontal direction and a second horizontal direction may each be defined as the horizontal direction perpendicular to the Z direction. The first horizontal direction may be referred to as the X direction, and the second horizontal direction may be referred to as the Y direction. A vertical level may refer to a height level in the vertical direction (the Z direction). The horizontal width in the first horizontal direction may refer to the length in the horizontal direction (X direction and/or Y direction), and the vertical length may refer to the length in the vertical direction (the Z direction).

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

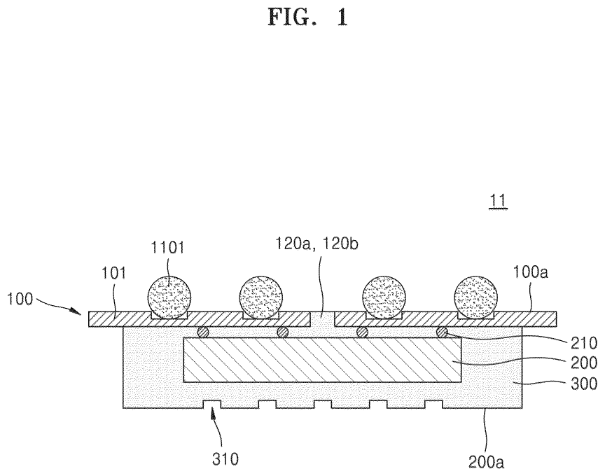

FIG. 1 is a cross-sectional view of a semiconductor package 11 that is a target of a method of detecting a defective semiconductor package, according to one or more embodiments.

Referring to FIG. 1, the semiconductor package 11 may include a package substrate 100, a semiconductor chip 200 mounted on the package substrate 100, an encapsulation layer 300 that encapsulates the semiconductor chip 200 on the package substrate 100, and a connection terminal 1101 attached to a rear surface 100a of the package substrate 100. In addition, in FIG. 1, the semiconductor chip 200 is mounted on the package substrate 100 via a chip connection terminal 210 in a flip chip manner, but embodiments are not limited thereto, and the method by which the semiconductor chip 200 is mounted is not limited to the flip chip method.

The package substrate 100 may be, for example, a printed circuit board (PCB). The package substrate 100 may include a substrate base 101 including one of phenol resin, epoxy resin, and polyimide.

The semiconductor chip 200 may be mounted on the package substrate 100. The semiconductor chip 200 may include an integrated circuit. The integrated circuit may be any type of integrated circuit including a memory circuit, a logic circuit, or combinations thereof. The memory circuit may include, for example, a dynamic random access memory (DRAM) circuit, a static random access memory (SRAM) circuit, a flash memory circuit, an electrically erasable and programmable read-only memory (EEPROM) circuit, a phase-change random access memory (PRAM) circuit, a magnetic random access memory (MRAM) circuit, a resistive random access memory (RRAM) circuit, or combinations thereof. The logic circuit may include, for example, a central processing unit (CPU) circuit, a graphics processing unit (GPU) circuit, a controller circuit, an application specific integrated circuit (ASIC) circuit, an application processor (AP) circuit, or combinations thereof.

The encapsulation layer 300 may seal the semiconductor chip 200 on the package substrate 100. In one or more embodiments, the encapsulation layer 300 may include an epoxy-group molding resin or a polyimide-group molding resin. For example, the encapsulation layer 300 may include an epoxy molding compound (EMC).

Window patterns 120a and 120b exposed through a vent hole may be formed on the rear surface 100a of the package substrate 100. The vent hole provides a passage through which air may be discharged with the encapsulation layer 300 configured to seal the semiconductor chip 200 of the semiconductor package 11. The encapsulation layer 300 fills the vent hole together with the inside of the semiconductor package 11 in which the semiconductor chip 200 is mounted, so that an encapsulation material exposed through the vent hole forms the window patterns 120a and 120b.

A package mark 310 may be formed on a front surface 200a of the encapsulation layer 300. The package mark 310 may be formed by etching the encapsulation layer 300 and may include information, such as the product name or serial number of the semiconductor package 11.

A plurality of connection terminals 1101 may be attached to the rear surface 100a of the package substrate 100. The plurality of connection terminals 1101 may be, for example, solder balls. The solder ball may also be referred to as a ball. A recess formed in the rear surface 100a near a region in which the connection terminal 1101 is placed may become a space in which a flux described below is placed.

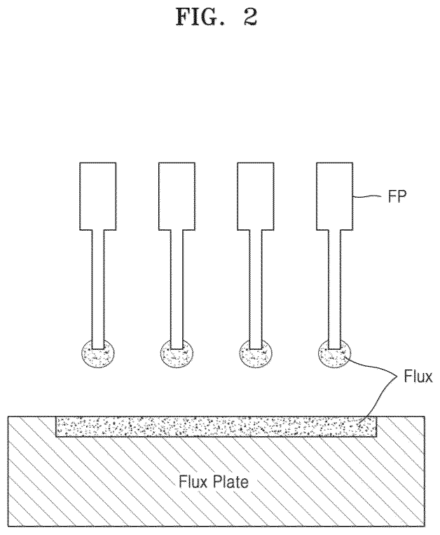

FIGS. 2 to 6 are cross-sectional views schematically illustrating a process of applying flux in a solder ball process of a semiconductor package that is a target of a method of detecting a defective semiconductor package, according to one or more embodiments.

Referring to FIG. 2, flux may be placed on an upper surface of a flux plate. The flux according to one or more embodiments may be one of a type of chemical mixture configured to remove oxides, activate surfaces, and improve bondability in a soldering process (metal bonding using solder balls or solder paste). Flux may be provided in a liquid, paste, or solid form and may be applied differently depending on the process environment.

As an example, flux may be utilized for deoxidation. As to be described below, a ball land in which a ball may settle and a surface of the solder ball (or solder paste) may naturally form an oxide film when in contact with air. The flux may chemically remove or suppress the oxide film and help ensure smooth metal-to-metal bonding.

As an example, the flux may be utilized for surface activation. As an example, the flux may be configured to lower the surface energy of the solder ball and the ball land, enabling the solder ball to spread and adhere more easily to a bonding surface.

The flux may include an activator, a vehicle, and additives. The activator may include a weak acid or a chlorinated compound, such as chloride. The vehicle may include a solvent (alcohol, water), or a paste may include a polymer material with relatively high viscosity. The additives may include viscosity modifiers, fluidity modifiers, etc.

A flux pin may be inserted into a flux plate in which the flux is located. The flux may be formed at the end of the flux pin, and such a process is referred to as flux dipping.

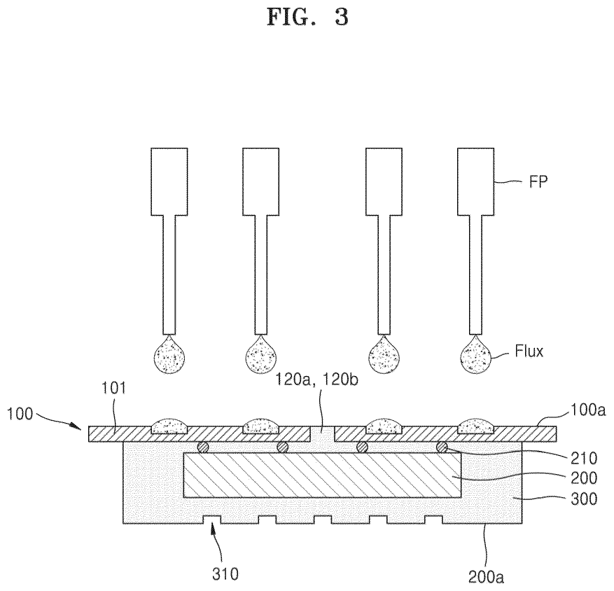

Referring to FIG. 3, when flux dipping is completed, the flux pin having the flux formed at the end may drop the flux onto the ball land of the rear surface 100a of the package substrate 100 or may directly contact the rear surface 100a of the package substrate 100 to place the flux on the ball land of the rear surface 100a. The package substrate 100 may be a PCB. Such a process is referred to as flux dotting.

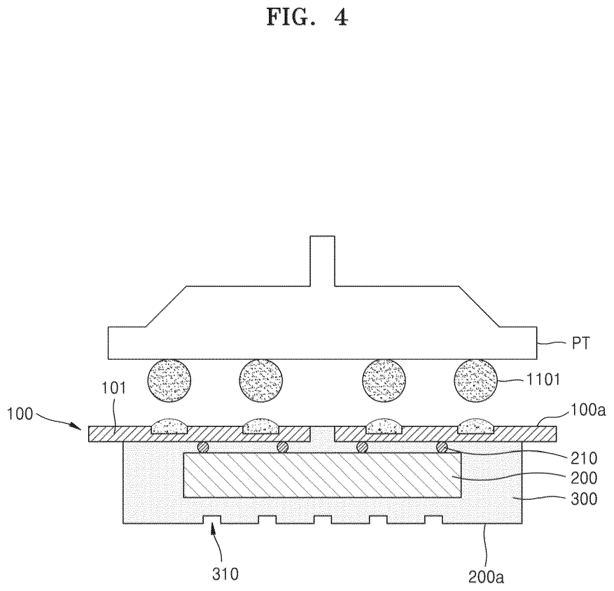

Referring to FIG. 4, a ball pickup operation of picking up the connection terminal 1101 may be performed using a pickup tool PT. After the ball pickup operation is performed, the picked-up connection terminal 1101 may be dotted on the rear surface 100a of the package substrate 100 on which flux dotting has been completed. This process is referred to as ball dotting.

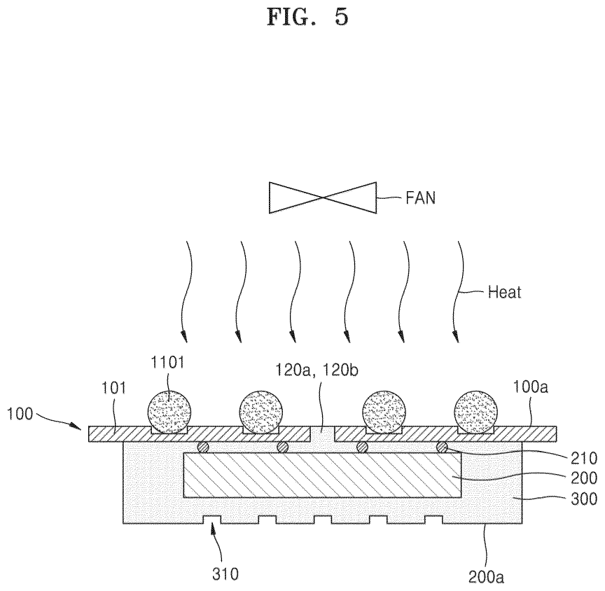

Referring to FIG. 5, heat may be applied to the rear surface 100a of the package substrate 100 on which ball dotting has been completed by using a fan. This process is referred to as a reflow soldering process. This is a process of forming a joint between the connection terminal 1101, which is a solder ball, and a ball land region of the PCB by heating using a fan. As an example, a fan-assisted heating method may be used in a reflow oven. The reflow soldering process may be segmented into four zones including a preheat zone, a soak zone, a reflow zone, and a cooling zone.

As an example, the preheat zone is a process of slowly heating the entire PCB to make the temperature of the entire PCB to be uniform. In this zone, the fan may supply hot air slowly to prevent thermal shock due to rapid temperature changes. For example, a temperature range of the preheat zone may be formed from 120° C. to 160° C.

In one or more embodiments, the soak zone is a process of stabilizing the temperature of the PCB and solder balls to complete preparation of soldering. For example, the soak zone is an operation in which the flux is fully activated, the oxide film is removed, and the surface is purified. For example, the temperature range of the soak zone may be formed from 160° C. to 200° C.

In one or more embodiments, the reflow zone is the highest temperature zone and corresponds to a process in which a portion of the solder ball melts and bonds with the ball land. The temperature at which the solder ball melts may vary depending on the solder alloy, but general solders may be formed at 180° C. and lead-free solders may be formed at 220° C.

In one or more embodiments, the cooling zone is the lowest temperature among the zones and may more rapidly cool the PCB and a solder joint to form a strong bond. For example, the temperature range of the cooling zone may be formed from 50° C. to 100° C.

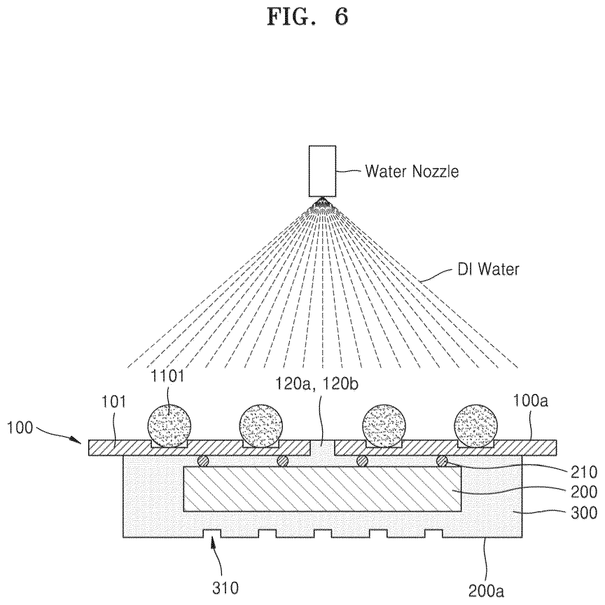

Referring to FIG. 6, a flux cleaning process may be performed on the rear surface 100a of the package substrate 100 on which reflow soldering has been completed, with deionized (DI) water sprayed from a water nozzle. This corresponds to a process of removing flux residue remaining on the surface of the package substrate 100. This process more effectively removes chemical residue of flux and improves the quality and reliability of a final product. The DI water according to one or more embodiments refers to deionized water, which may correspond to high-purity water obtained by removing cations and anions contained in water. DI water has low electrical conductivity and may not affect the electrical properties of the PCB during the cleaning process.

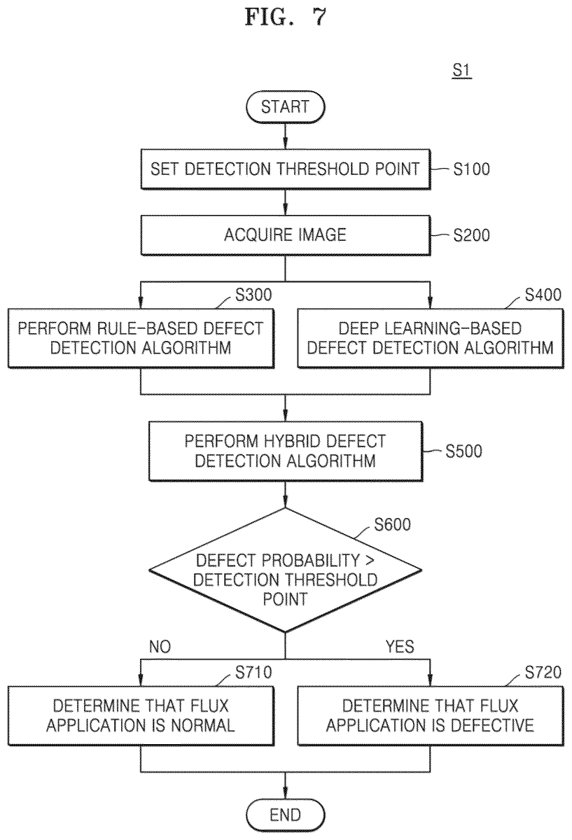

FIG. 7 is a flowchart of a method of detecting a defective semiconductor package, according to one or more embodiments.

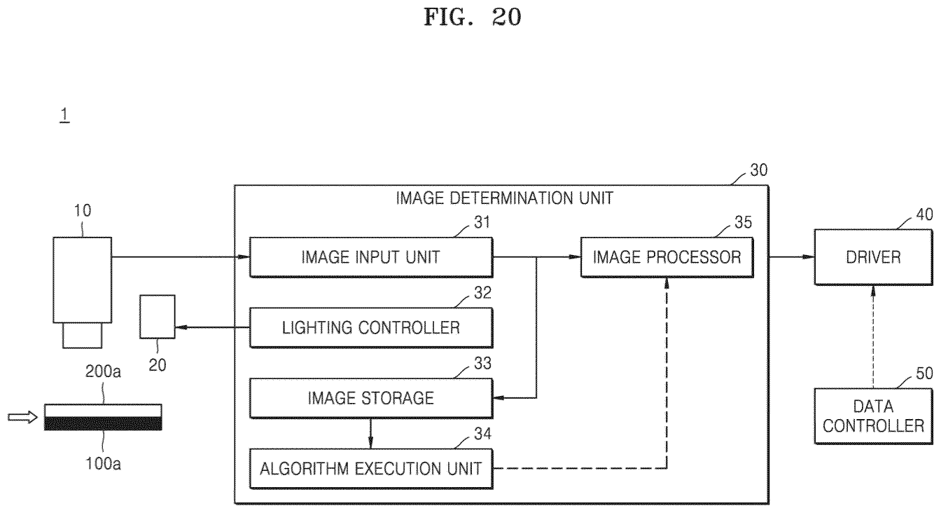

Referring to FIG. 7, the method of detecting a defective semiconductor package (S1) may include operation S100 of setting a detection threshold point, which is a reference point for determining a flux application defect. The detection threshold point may be a reference value compared with result values of a rule-based defect detection algorithm, deep learning-based defect detection algorithm, and hybrid defect detection algorithm described below. Operation S100 may be performed by a data controller 50 of FIG. 20.

The method of detecting a defective semiconductor package (S1) may include operation S200 of obtaining a target image of the rear surface of the package substrate 100, which is performed after operation S100. The target image may be an image of a target of which normality or abnormality of flux application is to be measured. The package substrate 100 shown in the target image may be the package substrate 100 of one semiconductor package 11. The package substrate 100 depicted in the target image may be, for example, a PCB. The package substrate 100 may include a substrate base including at least one material selected from phenol resin, epoxy resin, and polyimide. Additionally, the package substrate 100 may include a substrate lower pad arranged on a lower surface of the substrate base 101 and a connection terminal array attached to the lower pad. An internal interconnection pattern that is electrically connected to the substrate lower pad may be formed within the substrate base 101. The internal interconnection pattern may include a line pattern extending in the horizontal direction (the X direction or Y direction) within the package substrate 100 and a via pattern extending in the vertical direction (the Z direction) within the package substrate 100. The target image acquired in operation S200 may include not only a ball land image but also a flux image. The ball land image refers to an image of a ball land, which is a region in which a solder ball or ball of the inventive concept is to be dotted.

The method of detecting a defective semiconductor package (S1) may include operation S300 of performing a rule-based defect detection algorithm and operation S400 of performing a deep learning-based defect detection algorithm, which are performed after operation S200. Operation S300, which is an operation of performing a defect detection algorithm, and operation S400, which is an operation of performing a deep learning-based defect detection algorithm, may be performed simultaneously. Details of operations S300 and S400 are described with reference to the drawings below. Operations S300 and S400 may be performed by an algorithm execution unit 34 of FIG. 20.

The method of detecting a defective semiconductor package (S1) may include operation S500, which is an operation of performing a hybrid defect detection algorithm that is an algorithm that complements the strengths and weaknesses of each algorithm by analyzing the characteristics of the rule-based defect detection algorithm and the deep learning-based defect detection algorithm, after operations S300 and S400 are performed. In one or more embodiments, the hybrid defect detection algorithm may utilize the result values of performing each of the rule-based defect detection algorithm and the deep learning-based defect detection algorithm. Operation S500 may be performed by the algorithm execution unit 34 of FIG. 20.

The method of detecting a defective semiconductor package (S1) may include operation S600 of comparing a calculated or obtained defect probability with the size of a detection threshold point to determine whether there is a defect in the flux application of the package substrate, which is performed after operation S500. According to one or more embodiments, the defect probability determined in operation S600 may be calculated or obtained through the hybrid defect detection algorithm. The defect probability determined in operation S600 according to one or more embodiments may include a defect probability calculated or obtained after performing not only the hybrid defect detection algorithm but also the rule-based defect detection algorithm and the deep learning-based defect detection algorithm. Operation S600 may be performed by the data controller 50 of FIG. 20.

The method of detecting a defective semiconductor package (S1) may include operation S710 of determining that the flux application of the package substrate 100 is normal when the defect probability in operation S600 is lower than the detection threshold point and operation S720 of determining that the flux application is defective when the defect probability in operation S600 is greater than the detection threshold point. Operations S710 and S720 may be performed by the data controller 50 of FIG. 20.

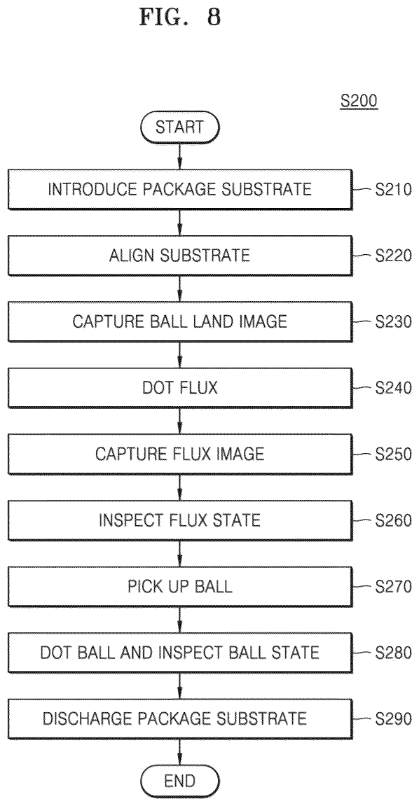

FIG. 8 is a flowchart of an operation of acquiring a target image included in the method of detecting a defective semiconductor package, according to one or more embodiments.

FIG. 8 is referred to together with FIG. 7. Operation S200, which is an operation of acquiring a target image, may include operation S210, which is an operation of introducing the package substrate 100. Operation S210 may be performed through a driver 40 of FIG. 20. Operation S200, which is an operation of acquiring a target image, may include operation S230 of capturing a ball land image performed after operation S210. Operation S210 may be performed through a camera 10 of FIG. 20, etc. The ball land image in operation S230 may refer to one surface of the package substrate 100 before flux is doted as described with reference to FIG. 3. In operation S210, a lighting controller 32 of FIG. 20 may be configured to change the brightness and wavelength of a lighting 20.

Operation S200, which is an operation of acquiring a target image, may include operation S240, which is an operation of dotting flux, which is performed after operation S230 is performed. Dotting flux may refer to that flux formed on a flux pin being dropped to be placed on the package substrate 100. Operation S240 may be performed as shown in FIG. 3. Operation S240 may be performed by the driver 40 of FIG. 20.

Operation S200, which is an operation of acquiring a target image, may include operation S250 of performing a flux image capturing inspection, which is performed after operation S240 is performed. The flux image captured in S250 may be imaging a region in which the flux settled on the package substrate 100 is placed. In operation S560, the lighting controller 32 of FIG. 20 may be configured to change the brightness and wavelength of the lighting 20. The images acquired in operations S230 and S250 may be input to an image input unit 31 included in an image determination unit 30 of FIG. 20. Thereafter, the image input to the image input unit 31 may be transmitted to an image processor 35.

Operation S200, which is an operation of acquiring a target image, may include operation S260 of inspecting a state of flux, which is performed after operation S250 is performed. The inspecting of the state of the flux may correspond to an operation of checking the shape and normal settlement of the flux itself, rather than capturing an image of the region in which the flux is placed.

Operation S200, which is an operation of acquiring a target image, may include operation S270 of picking up a ball, which is performed after operation S260 is performed. In operation S270, a ball may be picked up by a pickup tool PT as shown in FIG. 4. As described above, the ball according to one or more embodiments may be the connection terminal 1101. The pickup tool PT for picking up the ball may be controlled by the driver 40 of FIG. 20.

Operation S200, which is an operation of acquiring a target image, may include operation S280 of dotting a ball and inspecting the state of the ball, which is an operation performed after operation S270 is performed. In operation S280, the ball may be dropped from the pickup tool PT as shown in FIG. 4 and placed on the package substrate 100. After being placed on the package substrate 100, the pickup tool PT may come into physical contact with the flux, and the state of the ball may be inspected after the ball is in contact with the flux. When inspecting the ball in operation S280, an image of the shape of the dotted ball may be captured through the camera 10 of FIG. 20. Operation S200, which is an operation of acquiring a target image, may include operation S290 of discharging a package substrate, which is performed after operation S280 is performed.

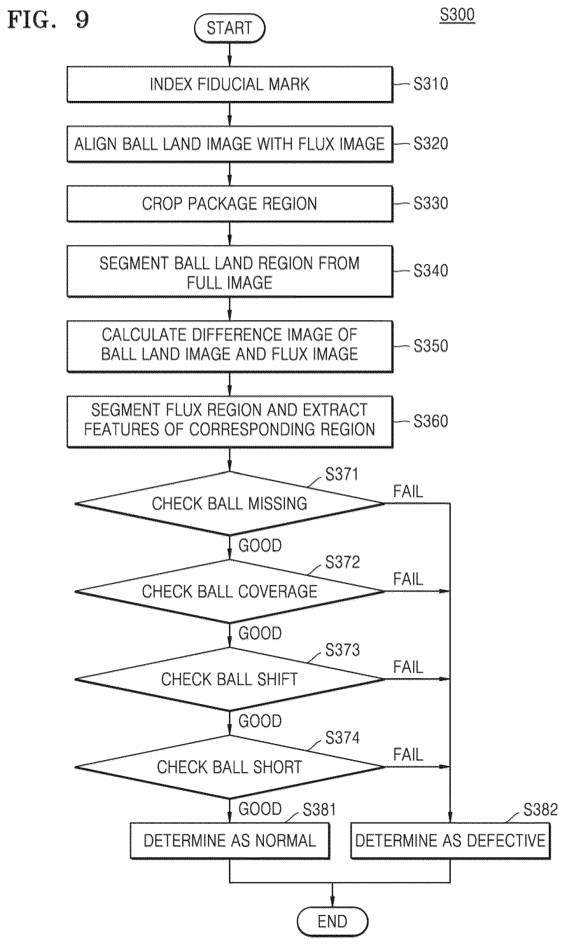

FIG. 9 is a flowchart of a rule-based defect detection algorithm included in a method of detecting a defective semiconductor package, according to one or more embodiments.

Operation S300, which is an operation of performing a rule-based defect detection algorithm, may include operation S310 of indexing a fiducial mark. In one or more embodiments, the fiducial mark refers to a mark used as a reference point for alignment and position confirmation. The fiducial mark is used to more accurately determine the position of a chip or substrate or to enable automated equipment (e.g., a pick-and-place machine, optical inspection equipment, etc.) to recognize the fiducial mark using a camera and perform alignment based on the fiducial mark. Operation S310 may be indexed by the camera 10 of FIG. 20.

Operation S300, which is an operation of performing a rule-based defect detection algorithm, may include operation S320 of performing alignment of the ball land image and the flux image, which is performed after operation S310. The ball land image aligned in operation S320 refers to the image captured in operation S230, and the flux image aligned in operation S320 refers to the image captured in operation S260. Operation S320 may be performed by the camera 10 and the driver 40 of FIG. 20.

Operation S300, which is an operation of performing a rule-based defect detection algorithm, may include operation S330 of cropping a package region, performed after operation S320. This indicates that a package region to be actually used is cropped from the aligned image in operation S320. Operation S330 may be performed by the image processor 35 and an image storage 33 included in the image determination unit 30 of FIG. 20.

Operation S300, which is an operation of performing a rule-based defect detection algorithm, may include operation S340 of segmenting a ball land region in the full image, performed after operation S330, and operation S350 of calculating or obtaining a difference image between the ball land image and the flux image. The full image in operation S340 refers to an image in which the ball land image overlaps the flux image in the package region cropped in operation S330. Operation S340 is a process of segmenting the ball land region to be used in operation S350. Operation S340 may be performed by the image processor 35 and the data controller 50 of FIG. 20. Operation S350 may be performed by [Equation 1].

$${g}^{′} ( x , y ) = \vert ( {g}_{1} ( x , y ) - {g}_{2} ( x , y ) ) \vert * w \qquad [ Equation 1 ]$$

In Equation 1, g(x, y) may refer to the gray value of each image. In Equation 1, w may denote a weight value, and the weight value w may be set to be different depending on the type of package, flux, and solder ball. Operation S350 may be performed by the data controller 50 of FIG. 20.

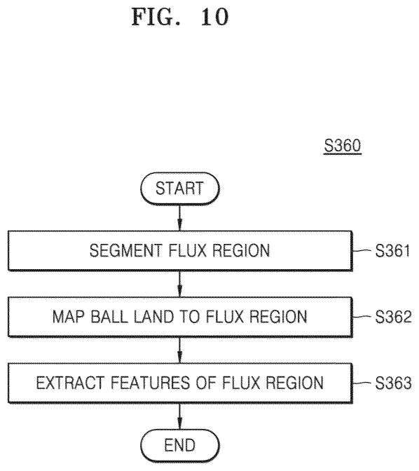

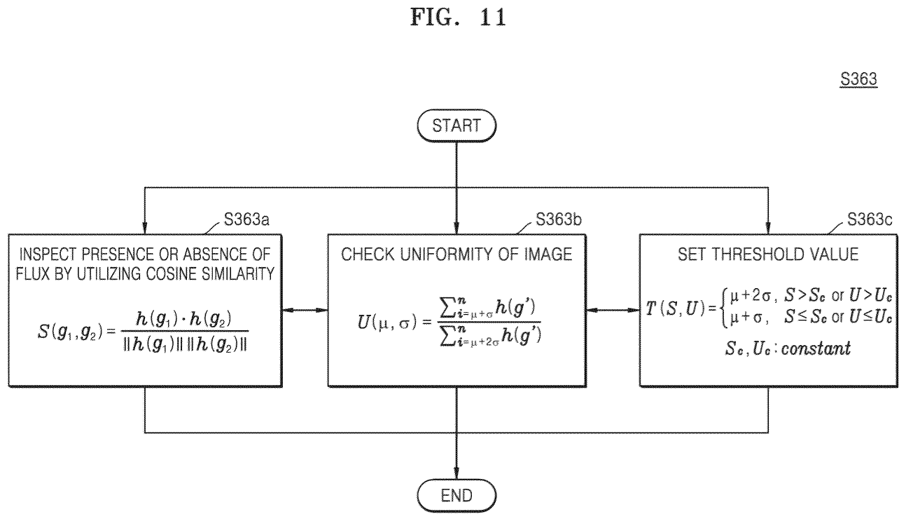

Operation S300, which is an operation of performing a rule-based defect detection algorithm, may include operation S360 of segmenting a flux region and extracting features of the region, which is performed after operation S350. Operation S360 is described in detail with reference to FIGS. 10 and 11.

Operation S300, which is an operation of performing a rule-based defect detection algorithm, may include operations S371 to S374 of determining whether the flux state is normal based on the features extracted in operation S360, which are performed after operation S360. In FIG. 9, operations S371 to S374 are illustrated serially, but the order of the operations may be switched and occur in a different order, or the operations may be performed simultaneously. Operation S371 is an operation of checking whether landed solder balls or balls are in the correct positions, as an operation of checking ball missing. Operation S372 is an operation of checking a region covered by the solder balls or balls, as a ball coverage operation. Operation S373 is an operation of checking a distance the solder balls or balls have moved in the horizontal direction from the positions in which the solder balls or balls should land, as an operation of checking a ball shift. Operation S374 is an operation of determining whether the solder balls or balls are attached to each other and shorted, as an operation of checking a ball short. In the operation of determining whether the flux state is normal, including operations S371 to S374, the flux state may be determined to be normal when all of the operations of checking ball missing, ball coverage, ball shift, and ball short are normal, and the flux state may be determined to be defective when at least one of the operations of checking ball missing, ball coverage, ball shift, and ball short is defective. Therefore, operation S381, in which the flux state is determined to be normal, may consequently correspond to operation S710 of FIG. 7. In addition, operation S382, in which the flux state is determined to be defective, may consequently correspond to operation S720 of FIG. 7. Operations S371 to S374 may be performed by the algorithm execution unit 34, the image processor 35, and the data controller 50 of FIG. 20.

FIG. 10 is a flowchart of operations of segmenting a flux region and extracting features of the corresponding region, included in a method of detecting a defective semiconductor package, according to one or more embodiments. FIG. 11 is a flowchart of an operation of extracting features of a flux region included in a method of detecting a defective semiconductor package, according to one or more embodiments.

FIGS. 10 and 11 are referred to together with FIG. 9. Operation S360 of segmenting a flux region and extracting features of the corresponding region may include operation S361 of segmenting a flux region, operation S362 of mapping each region of the ball land and flux, performed after operation S361, and operation S363 of extracting features of the flux region, performed after operation S362. Operations S361 to S363 may all be performed by the algorithm execution unit 34 of FIG. 20. Mapping the regions of each of the ball land and flux of the inventive concept refers to a process of precisely aligning the positions of two regions to fit each other. In the case of mapping, after performing an optical inspection through the camera 10 of FIG. 20, each position may be confirmed and then aligned.

Operation S363 may be performed in three ways as illustrated in FIG. 11.

First, operation S363a may correspond to a flux presence check using the similarity derived using cosine similarity. Operation S363a may be performed by [Equation 2] below.

$$S ( {g}_{1} , {g}_{2} ) = \frac{h ( {g}_{1} ) \cdot h ( {g}_{2} )}{‖ h ( {g}_{1} ) ‖ ‖ h ( {g}_{2} ) ‖} \qquad [ Equation 2 ]$$

The S function in operation S363a stands for similarity. The h function represents a histogram function for each gray value. In h(g), g stands for g(x,y), a gray value described above, which means a brightness value of an image with an (x, y) coordinate system. h(g) denotes a brightness distribution of g. Each of h(g₁) and h(g₂) may correspond to a vector having a size of 256. This is because the brightness value of an 8-bit image ranges from 0 to 255. The numerator of the similarity function is the inner product of each vector. The denominator of the similarity function is the product of the lengths of the Euclidean distances of each vector. The size of S may have a value between 0 and 1. g1 and g2 represent the images after flux application and before flux application, respectively.

Operation S363a corresponds to an operation of checking whether flux is actually present in the image after flux application. To check the presence of flux, the brightness histograms of the images before and after flux application are obtained, and each histogram is converted into a vector. The similarity between the transformed vectors may be derived using the cosine similarity formula as in <Equation 2>. Thereafter, if the similarity exceeds a certain value, it is determined that no flux has been applied. The certain value here may vary depending on the initial settings.

Second, operation S363b may correspond to checking the uniformity of the image. Operation S363b may be performed by [Equation 3] below.

$$U ( μ , σ ) = \frac{{\sum }_{i = μ + σ}^{n} h ( {g}^{′} )}{{\sum }_{i = μ + 2 σ}^{n} h ( {g}^{′} )} \qquad [ Equation 3 ]$$

The U function in operation S363b stands for uniformity. In Equation 3, μ is an average brightness value of the g′ (x,y) image, which is a difference image, and σ stands for standard deviation. The g′ function refers to a difference image, that is, the brightness values of g₁ and g₂ are subtracted from each other, assuming that there are images g₁ and g₂. Therefore, h(g′) may be a brightness distribution obtained using the difference image g′.

In operation S363b, a brightness histogram of the image obtained from the difference image may be obtained and how spread out the distribution of the histogram is may be calculated or obtained. The sharpness of the flux region may vary depending on how spread out the distribution is. The uniformity of the distribution may be obtained by calculating or obtaining the ratio of the sum of the brightness values included in a 1-sigma range to the sum of the brightness values included within a 2-sigma range.

Thirdly, in operation S363c, a threshold value may be set. Operation S363 may be performed by [Equation 4] below.

$$T ( S , U ) = \{ \begin{matrix}μ + 2 σ , S > {S}_{c} or U > {U}_{c} \\ μ + σ , S \leq {S}_{c} or U \leq {U}_{c}\end{matrix} \qquad [ Equation 4 ]$$

$${S}_{c} , {U}_{c} : constant$$

The function described in operation S363c is the same as the function described above. However, S_{c}, U_{c} corresponds to a constant value for each function, and the constant value may change depending on a value set by the data controller 50.

In operation S363c, the threshold value for binarization of the flux region using the similarity and uniformity values obtained in S363a and S363b may be set. The threshold value, similar to the constant value, is merely an experimental value and may be set to be different during the process of executing the algorithm.

The features extracted in operations S363a to S363c may be used to determine whether the flux application state is normal or as a result value for performing a hybrid defect detection algorithm.

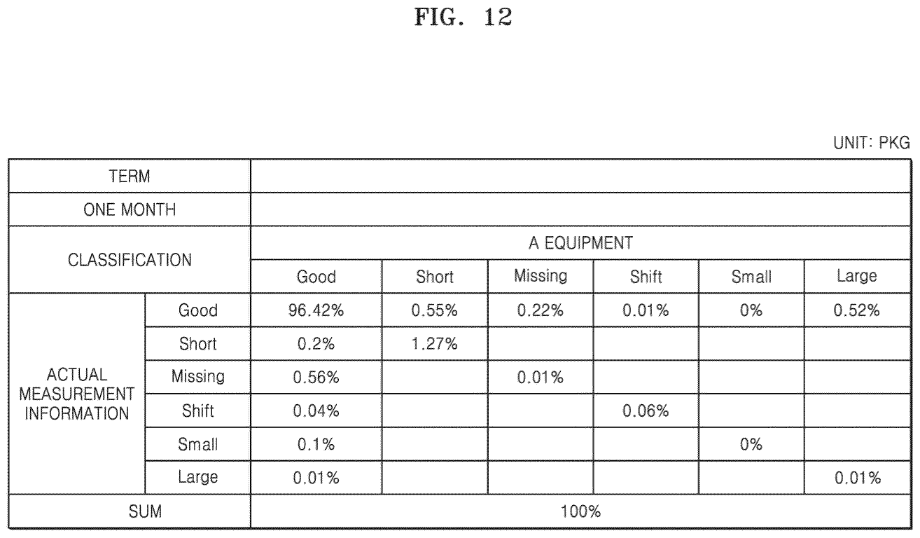

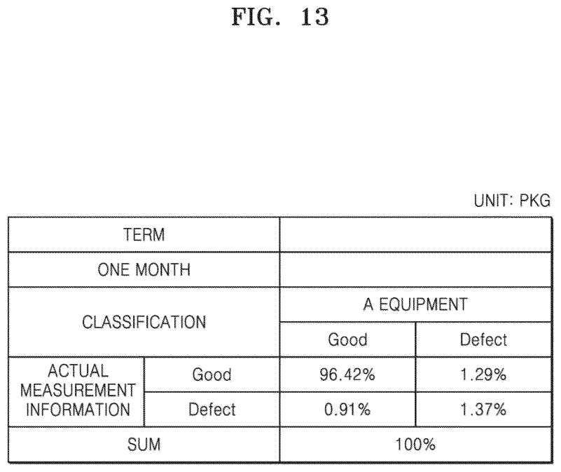

FIGS. 12 and 13 are results of simulations of a rule-based defect detection algorithm included in a method of detecting a defective semiconductor package, according to one or more embodiments.

FIGS. 12 and 13 are referred to together. The result values of a simulation conducted for approximately one month on 8 units of equipment A for the rule-based defect detection algorithm are shown.

Good refers to a product with no defects, and anything other than Good refers to a type of defect.

The unit in FIG. 12 is one unit of a package. Below, the probability, which is the number of cases for all parameters, is expressed as %. The figure for which the actual measurement information was accurately determined as Good was 96.42%. However, the value determined as defective for short, missing, shift, large, etc., despite the actual measurement information being good, was 3.58%. This 3.58% corresponds to an overkill value of the rule-based defect detection algorithm. For example, overkill refers to an error of judging a real product as defective.

In addition, cases in which defective actual measurement information was determined as defective were 1.24% for short, 0.01% for missing, 0.06% for shift, and 0.01% for large. These figures correspond to the figures that accurately judge a defect to be a defect.

There were cases of underkill in which products were determined to be good even though the actual measurement information was defective. When the figures for each case are listed, there is a figure of 0.2% for judging short defects as good, 0.56% for judging missing defects as good, 0.04% for judging shift defects as good, 0.1% for judging small defects as good, and 0.01% for judging large defects as good. For example, underkill refers to the error of judging an actual defective product as a good product.

FIG. 13 is a diagram that sums the values of FIG. 12. For example, in the case of the rule-based defect detection algorithm, the inspection accuracy is 97.79%, which is a value for judging a good product as a good product and a defective product as a defective product. Overkill, which judges a good product as defective, corresponds to 1.29%, and underkill, which judges a defective product as good, corresponds to 0.91%. For example, even the rule-based algorithm is not able to completely judge all good and bad products and has shortcomings that overkill is slightly greater than underkill. These shortcomings may be used in a hybrid defect detection algorithm by referring to the results of a deep learning-based defect detection algorithm that are described below.

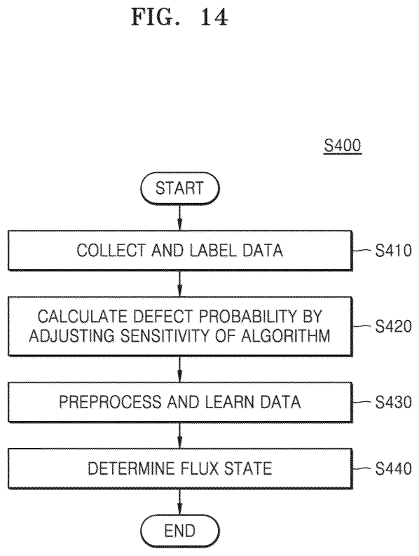

FIG. 14 is a flowchart of a deep learning-based defect detection algorithm included in a method of detecting a defective semiconductor package, according to one or more embodiments.

FIG. 14 is a detailed flowchart of the deep learning-based defect detection algorithm of FIG. 7, in which operation S400 of performing the deep learning-based defect detection algorithm may include operation S410 of collecting data and performing labeling on the collected data, operation S420 of calculating or obtaining a defect probability by adjusting the sensitivity of the deep learning algorithm, operation S430 of performing preprocessing and learning on data including the defect probability calculated or obtained in S420, which is performed after operation S420, and operation S440 of determining a flux state through the learned deep learning algorithm. Operations S410 to S440 may be performed by the algorithm execution unit 34 of FIG. 20.

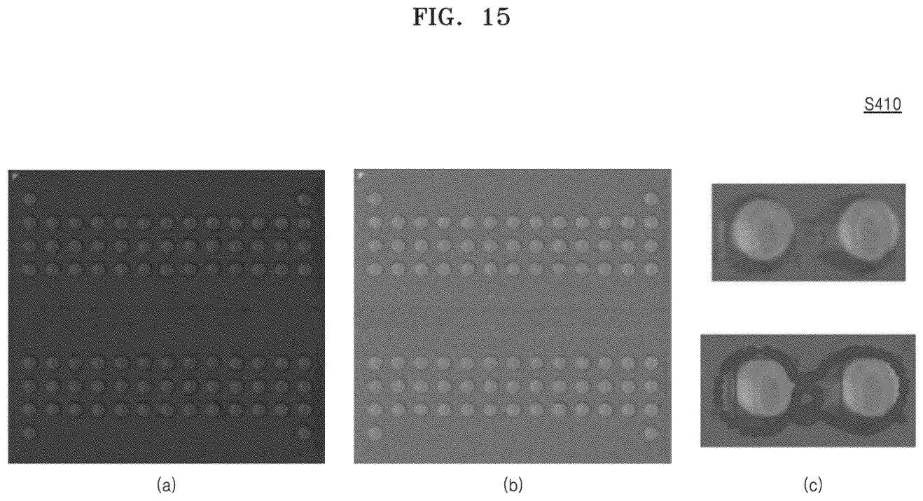

In operation S410, data may be collected to secure an image learning model. In operation S410, data may be collected manually or automatically. Details on operation S410 are shown in FIG. 15.

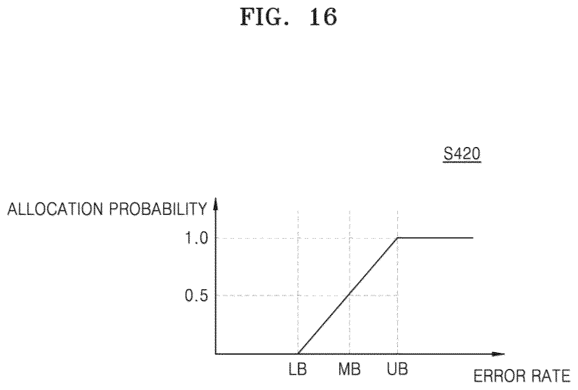

In operation S420, the defect probability may be calculated or obtained after labeling to give a weight according to the degree of defects. Error rates for weights and weights according to defects are described below with reference to FIG. 16.

FIG. 15 is a diagram illustrating an operation of performing data collection and labeling included in a method of detecting a defective semiconductor package, according to one or more embodiments.

Referring to FIG. 15, operation S410 is illustrated, and (a) illustrates the original image for learning. The image shows balls arranged on a package substrate. The balls may be placed on the flux. (b) is an image of (a) with brightness adjusted by the lighting controller 32 of FIG. 20. After adjusting the brightness, when the shapes of the balls are clearly distinguishable, the extent of a defect may be identified in the image. (c) shows the labeling performed on the extent of a defect specified in image (b). Referring to (c), it may be confirmed that labeling is performed on a cropped image including two balls.

FIG. 16 is a graph illustrating a defect probability for an algorithm sensitivity included in a method of detecting a defective semiconductor package, according to one or more embodiments.

Referring to FIG. 16, an allocation probability for error rates is illustrated. Each error probability on the X-axis has the following meaning. As an example, a lower boundary LB, which is the degree of defect at which an output probability value of a network becomes 0. As an example, middle of two boundaries MB, which is the degree of defect at which the output probability value of the network is 0.5. As an example, an upper boundary UB, which is the degree of defect at which the output probability of the network becomes 1.

As an example, when a ball short defect of 100 μm or more is to be selected as a defect in a ball short defect, the sensitivity of the detection algorithm may be adjusted by flexibly adjusting the LB, MB, and UB values.

For example, in a first case, the LB value is set to 90, the MB value is set to 100, and the UB value is set to 110. For example, when the sizes of the shorts are 90, 100, and 110, respectively, learning may be performed so that the short defect probability values output by the network are 0%, 50%, and 100%, respectively.

For example, in a second case, the LB value is set to 80, the MB value is set to 900, and the UB value is set to 100. For example, when the sizes of the shorts are 80, 90, and 100, respectively, learning may be performed so that the short defect probability values output by the network are 0%, 50%, and 100%, respectively.

The second case may be trained to be more sensitive to shorts than the first case.

A case in which the value of the short is 95, including both the first and second cases, is calculated or obtained. In the second case, the network may output a 75% defect probability, which may be determined as defective. In the first case, the network may output a 25% defect probability, so it may be determined as normal.

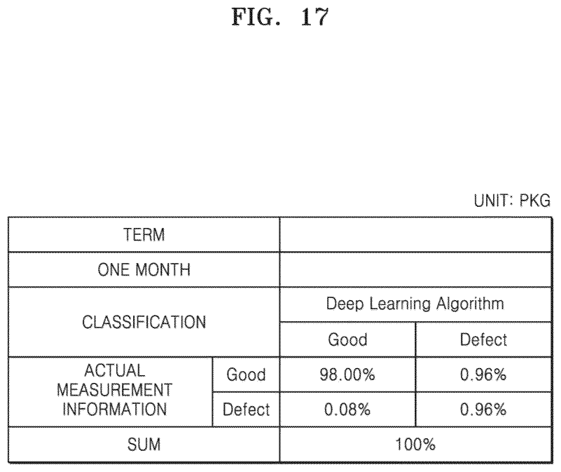

FIG. 17 is result values for a simulation of a deep learning-based defect detection algorithm included in a method of detecting a defective semiconductor package, according to one or more embodiments.

FIG. 17 is referred to. The results are shown after performing a simulation for about a month on 8 pieces of equipment for the deep learning defect detection algorithm.

A good product without any defects is considered Good, and a product that is not Good is considered Defect.

The unit in FIG. 17 is one unit of package. Below, the probability, which is the number of cases for all parameters, is expressed as %.

A case in which actual measurement information of a good product is determined to be good product corresponds to 98%. A case in which a defective actual measurement information is determined as defective corresponds to 0.96%. Therefore, the accuracy of the inspection is 96.96%.

In the case of overkill, in which the actual measurement information of a good product is determined as defective, the rate is 0.96%. In addition, in the case of underkill, in which the actual measurement information of a defect is determined as good, the rate is 0.06%.

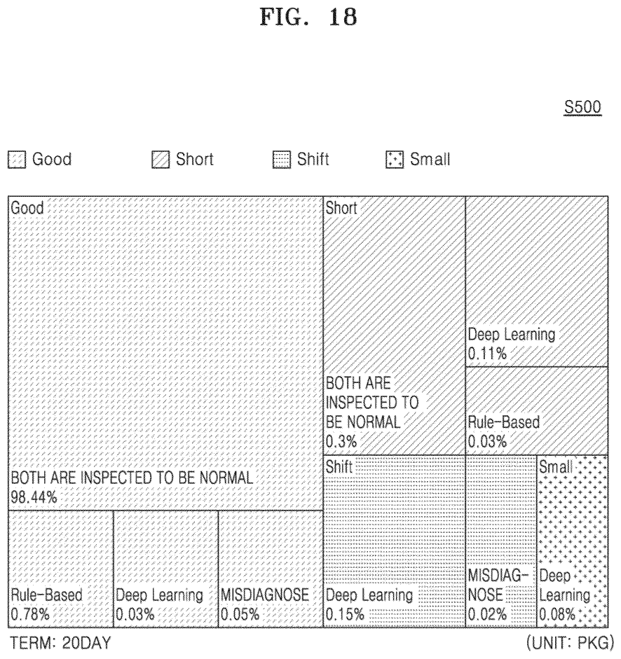

FIG. 18 is a diagram illustrating data for performing a hybrid defect detection algorithm included in a method of detecting a defective semiconductor package, according to one or more embodiments.

Referring to FIG. 18, the merged result values for performing the hybrid defect detection algorithm are illustrated. For example, the result values of each algorithm for comparing the performance of the rule-based defect detection algorithm and the deep learning-based defect detection algorithm are merged. A combination of algorithms that complement each other's strengths and weaknesses by comparing the performance of the rule-based defect detection algorithm and the deep learning-based defect detection algorithm corresponds to the hybrid defect detection algorithm.

Referring to the data described with reference to FIG. 18, as an example, it is assumed that all parameters of an actual good product are 100%. Among the parameters of good products, 98.44% were inspected accurately as good products by both rule-based and deep learning algorithms. Among the parameters of good products, 0.78% were inspected correctly as good products only by the rule-based algorithm. Among the parameters of good products, 0.03% were inspected correctly as good products only by the deep learning algorithm. Among the parameters of the good products, 0.05% were abnormally misdiagnosed by both rule-based and deep learning algorithms.

Next, the measurement parameters of actual short defects are determined based on the overall parameters. In the parameter of short defects, 0.3% were correctly inspected as short defects by both rule-based and deep learning algorithms. In the parameter of short defects, 0.03% were correctly inspected as short defects only by the rule-based algorithm. In the parameter of short defects, 0.11% were correctly inspected as short defects only by deep learning algorithms.

In one or more embodiments, the measurement parameters of actual shift defect are determined based on the overall parameters. In the parameter of shift defects, 0.15% were correctly detected as a short defects by the deep learning algorithm. Among the shift defect parameters, 0.02% were abnormally misdiagnosed by both rule-based and deep learning algorithms.

As an example, when judging the parameters of actual small defects based on all the parameters, the deep learning algorithm correctly inspected all parameters of small defects as small defects.

As described above, it can be seen that the accuracy of execution of each of the rule-based algorithm or deep learning algorithm differs depending on the type of each defect. Utilizing the result values for these accuracies and re-verifying combinations of only the strengths of each algorithm with multiple machine learning ensemble algorithms may be considered hybrid defect detection.

The hybrid defect detection algorithm may utilize at least one of a multi-layer perceptron (MLP) model, a logistic regression model, a random forest model, a support vector machine, and a naïve algorithm.

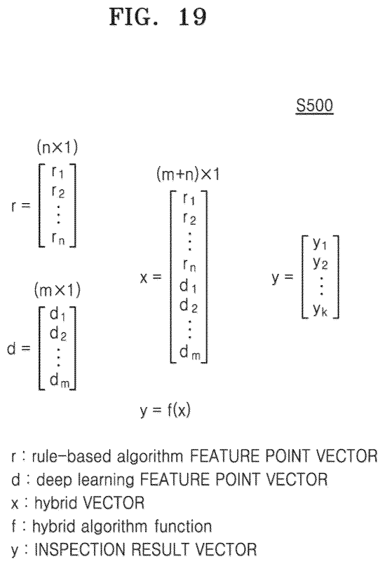

The MLP model refers to an artificial neural network algorithm including multiple layers. Logistic regression is a model that predicts the probability that data belongs to a certain category as a value between 0 and 1. The random forest model is a model that generates multiple decision trees and derives a final result through voting. The support vector machine is an algorithm that finds the optimal boundary between good and bad judgments by considering each result as a feature. Lastly, the naive algorithm is a model that predicts an outcome by utilizing the weighted sum of each outcome. Details on the vectors that form the hybrid algorithm are described with reference to FIG. 19.

FIG. 19 is a diagram illustrating vectors representing the logic of a hybrid defect detection algorithm included in a method of detecting a defective semiconductor package, according to one or more embodiments.

Referring to FIG. 19, the hybrid defect detection algorithm may combine a feature vector of the rule-based defect detection algorithm and a feature vector of the deep learning-based defect detection algorithm.

“r vector” is a feature vector of the rule-based defect detection algorithm and includes feature points extracted from the rule-based algorithm. As an example, the size of the r vector may be n×1.

“d vector” is a feature vector of a deep learning defect detection algorithm and includes feature points extracted from the deep learning algorithm. As an example, the size of the d vector may be m×1.

“x vector” is a vector that combines the r vector and the d vector and is a vector of the hybrid defect detection algorithm. As an example, the size of the x vector may be (m+n)×1 and may include richer data by combining the strengths of both algorithms.

“y vector” represents a result value of the hybrid defect detection algorithm. As an example, the size of the y vector may be k×1.

FIG. 20 is a configuration diagram illustrating a defective semiconductor package detection device 1 for implementing a method of detecting a defective semiconductor package, according to one or more embodiments.

Referring to FIG. 20, the semiconductor package defect detection device 1 according to one or more embodiments includes the camera (or a video camera) 10 for imaging the rear surface 100a of the package substrate (100, see FIG. 1) placed on an inspection stand as illustrated in FIG. 1, the image determination unit 30 receiving an image signal from the image camera 10 and determining whether the image signal is normal, the lighting 20 installed for clarity of an image of a fine portion, the driver 40 controlling and driving a programmable logic controller (PLC) according to a determination result from the image determination unit 30, and the data controller 50 transmitting a control signal to the driver 40 based on information accumulated after being received from the image determination unit 30.

The camera 10 used for detecting a defective semiconductor package according to one or more embodiments is a high-resolution differential interference camera. Such a differential interference camera may capture images incident from a lens more clearly by applying differential interference contrast (DIC) filters, polarizing filters, and analysis filters inside an optical tube. The camera 10 may be a camera that captures still images, or without being limited thereto, a line scan camera may be applied to capture a panel while the inspection table moves at a constant speed. Here, when the line scan camera is used, the rear surface 100a of the package substrate (100, see FIG. 1) is continuously imaged to provide image data, so the judgment operation is also processed in batches, which has the advantage of simplifying the entire processing process. The lighting 20 may include an LED, and light being irradiated (emitted) may have a wavelength of about 400 to 500 nm. Due to the lighting unit, the camera 10 may capture a clearer image of the rear surface 100a of the package substrate (100, see FIG. 1).

The image determination unit 30 includes the image input unit 31 that receives an image from the camera 10, the lighting controller 32 connected to the lighting 20 and controlling and transmitting a driving control signal for the lighting 20, the image storage 33 that stores an image input from the camera 10 to the image input unit 31, and the algorithm execution unit 34 configured to detect the position of a window pattern based on an algorithm from an image received from the image input unit 31.

The data controller 50 may be configured to transmit a control signal to the driver 40 based on information accumulated after being received from the image determination unit 30. The data controller 50 may include, for example, a machine analysis and re-engineering system (MARS).

According to one or more embodiments, after detecting whether the window patterns 120a and 120b formed on the rear surface 100a of the package substrate (100, see FIG. 1) are defective, the semiconductor package 11 may be turned over and whether the package mark 310 formed on the front surface of the encapsulation layer (300, see FIG. 1) is defective may be detected.

At least one of the components, elements, modules or units (collectively “components” in this paragraph) represented by a block in the drawings, such as image determination unit in FIG. 20, may be embodied as various numbers of hardware, software and/or firmware structures that execute respective functions described above, according to an exemplary embodiment. For example, at least one of these components may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU) that performs the respective functions, a microprocessor, or the like. Two or more of these components may be combined into one single component which performs all operations or functions of the combined two or more components. Also, at least part of functions of at least one of these components may be performed by another of these components. Further, although a bus is not illustrated in the above block diagrams, communication between the components may be performed through the bus. Functional aspects of the above exemplary embodiments may be implemented in algorithms that execute on one or more processors. Furthermore, the components represented by a block or processing steps may employ any number of related art techniques for electronics configuration, signal processing and/or control, data processing and the like.

While embodiments have been described with reference to the figures, it will be understood by those of ordinary skill in the art that various changes in form and details may be made therein without departing from the spirit and scope as defined by the following claims and their equivalents.

What is claimed is:

1. A method of detecting a defective semiconductor package, the method comprising:
setting a detection threshold point, which is a reference point to determine a defective flux application;
obtaining a target image of a first surface of a package substrate;
performing a rule-based defect detection algorithm on the target image;
performing a deep learning-based defect detection algorithm on the target image;
performing a hybrid defect detection algorithm based on a result value of performing the rule-based defect detection algorithm and a result value of performing the deep learning-based defect detection algorithm; and
comparing a defect probability obtained based on the hybrid defect detection algorithm with a size of the detection threshold point to determine whether the flux application of the package substrate is defective.

2. The method of claim 1, wherein in the determining of whether the flux application of the package substrate is defective:
the flux application of the package substrate is determined to be normal based on the defect probability being smaller than the detection threshold point, and
the flux application of the package substrate is determined to be defective based on the defect probability being greater than the detection threshold point.

3. The method of claim 1, wherein the acquiring of the target image comprises:
introducing the package substrate;
aligning the introduced package substrate;
dotting flux onto the package substrate;
picking up a ball to be attached to the flux;
dotting the ball and checking a state of the ball; and
discharging the package substrate.

4. The method of claim 3, wherein the obtaining of the target image comprises:
capturing a ball land image of the package substrate, which is performed after aligning the package substrate;
capturing the flux image, which is performed after dotting the flux; and
checking a state of the flux.

5. The method of claim 4, wherein a semiconductor package defect detection device comprises at least one processor, and
wherein the at least one processor is configured to change a brightness of lighting and a wavelength of the lighting in the capturing of the ball land image and the capturing of the flux image.

6. The method of claim 5, wherein the rule-based defect detection algorithm comprises:
indexing a fiducial mark on the package substrate;
aligning the ball land image with the flux image;
cropping a package region from a full image obtained by adding the aligned ball land image to the flux image;
segmenting a ball land region from the full image;
obtaining a difference image between the ball land image and the flux image;
segmenting a flux region from the full image; and
extracting features of the segmented region.

7. The method of claim 6, wherein the rule-based defect detection algorithm comprises determining whether the state of the flux is normal based on the features extracted from the segmenting the flux region from the full image and extracting the features of the segmented region, and
wherein the determining of whether the state of the flux is normal comprises checking each of ball missing, ball coverage, ball shift, and ball short.

8. The method of claim 6, wherein the segmenting of the flux region and the extracting the features of the segmented region comprises inspecting the presence or absence of flux based on a similarity derived based on cosine similarity, checking a uniformity of an image of the difference image, and setting a threshold value based on the similarity and the uniformity.

9. The method of claim 8, wherein the deep learning-based defect detection algorithm comprises:
performing data collection and labeling;
obtaining the defect probability by adjusting a sensitivity of an algorithm;
performing preprocessing and learning on obtained data that comprises the defect probability; and
determining the state of the flux based on a trained deep learning model.

10. The method of claim 9, wherein the hybrid defect detection algorithm comprises a vector combining a feature point vector of the rule-based defect detection algorithm and a feature point vector of the deep learning-based defect detection algorithm.

11. A method of detecting a defective semiconductor package, the method comprising:
setting a detection threshold point, which is a reference point to determine a defective flux application;
obtaining a target image of a first surface of a package substrate;
performing a rule-based defect detection algorithm on the target image;
performing a deep learning-based defect detection algorithm on the target image;
performing a hybrid defect detection algorithm based on a result value of performing the rule-based defect detection algorithm and a result value of performing the deep learning-based defect detection algorithm; and
comparing a defect probability obtained through the hybrid defect detection algorithm with a size of the detection threshold point to determine whether the flux application of the package substrate is defective,
wherein, in the determining of whether the flux application of the package substrate is defective, the flux application of the package substrate is determined to be normal based on the defect probability being smaller than the detection threshold point, and the flux application of the package substrate is determined to be defective based on the defect probability being greater than the detection threshold point, and
wherein the acquiring of the target image comprises:
introducing the package substrate;
aligning the introduced package substrate;
capturing a ball land image of the package substrate;
dotting flux on the package substrate;
capturing an image of the flux;
inspecting a state of the flux;
picking up a ball to be attached to the flux;
dotting the ball and inspecting a state of the ball; and
discharging the package substrate.

12. The method of claim 11, wherein a semiconductor package defect detection system comprises at least one processor, and
wherein the at least one processor is configured to change a brightness of lighting and a wavelength of the lighting in each of the capturing of the ball land image and the capturing of the flux image.

13. The method of claim 11, wherein the rule-based defect detection algorithm comprises:
indexing a fiducial mark on the package substrate;
aligning the ball land image with the flux image;
cropping a package region from a full image obtained by adding the aligned ball land image to the flux image;
segmenting the ball land region from the full image;
obtaining a difference image between the ball land image and the flux image; and
segmenting a flux region from the full image and extracting features of the segmented region.

14. The method of claim 13, wherein the rule-based defect detection algorithm comprises determining whether the state of the flux is normal based on the features extracted from the segmenting of the flux region from the full image and the extracting of the features of the segmented region,
wherein the determining of whether the state of the flux is normal comprises checking each of ball missing, ball coverage, ball shift, and ball short,
wherein the state of the flux is determined to be normal based on all of the operations of checking the ball missing, ball coverage, ball shift, and ball short being normal and
wherein the state of the flux is determined to be defective based on at least one of the operations of checking the ball missing, ball coverage, ball shift, and ball short being defective.

15. The method of claim 13, wherein the segmenting of the flux region and extracting the features of the segmented region comprises:
segmenting the flux region;
mapping the ball land to the flux region; and
extracting features of the flux region,
wherein the extracting of the features of the flux region comprises inspecting the presence or absence of flux based on a similarity derived based on cosine similarity, checking a uniformity of an image of the difference image, and setting a threshold value based on the similarity and the uniformity.

16. The method of claim 15, wherein the deep learning-based defect detection algorithm comprises:
performing data collection and labeling;
obtaining a defect probability by adjusting sensitivity of the algorithm;
performing preprocessing and learning on obtained data that comprises the defect probability; and
determining the state of the flux based on a trained deep learning model.

17. The method of claim 16, wherein the hybrid defect detection algorithm comprises a vector obtained by combining a feature point vector of the rule-based defect detection algorithm with a feature point vector of the deep learning-based defect detection algorithm.

18. The method of claim 11, wherein the package substrate comprises a printed circuit board.

19. A method of detecting a defective semiconductor package, the method comprising:
setting a detection threshold point, which is a reference point to determine a defective flux application;
obtaining a target image of a first surface of a printed circuit board (PCB);
performing a rule-based defect detection algorithm on the target image;
performing a deep learning-based defect detection algorithm on the target image;
performing a hybrid defect detection algorithm based on a result value of the performing each of the rule-based defect detection algorithm and based on a result value of the deep learning-based defect detection algorithm; and
comparing a defect probability obtained through the hybrid defect detection algorithm with a size of the detection threshold point to determine whether the PCB is defective,
wherein, in the determining of whether the PCB is defective, a flux application on the PCB is determined to be normal based on the defect probability being smaller than the detection threshold point, and the flux application on the PCB is determined to be defective based on the defect probability being greater than the detection threshold point,
wherein the obtaining of the target image comprises:
introducing a PCB;
aligning the introduced PCB;
capturing a ball land image of the PCB;
dotting flux onto the PCB;
capturing an image of the flux;
inspecting a state of the flux;
picking up a ball to be attached to the flux;
dotting the ball and inspecting a state of the ball; and
discharging the PCB,
wherein the rule-based defect detection algorithm comprises:
indexing a fiducial mark on the PCB;
aligning the ball land image with the flux image;
cropping a package region from a full image obtained by adding the aligned ball land image to the flux image;
segmenting a ball land region from the full image;
obtaining a difference image between the ball land image and the flux image;
segmenting a flux region from the full image and extracting features of the segmented region; and
determining whether the state of the flux is normal based on the features extracted from the segmenting the flux region in the full image and extracting the features of the segmented region, and
wherein the hybrid defect detection algorithm comprises a vector combining a feature point vector of the rule-based defect detection algorithm and a feature point vector of the deep learning-based defect detection algorithm.

20. The method of claim 19, wherein the rule-based defect detection algorithm and the deep learning-based defect detection algorithm are each performed simultaneously.
